(19) United States
(12) Patent Application Publication
(10) Pub. No.: US 2024/0263338 A1
(43) Pub. Date: Aug. 8, 2024

(54) GRADED TIP CUPROUS OXIDE SINGLE CRYSTAL MATERIAL AND PREPARATION METHOD AND APPLICATION THEREOF

(71) Applicant: Nankai University, Tianjin (CN)

(72) Inventors: Fangyi CHENG, Tianjin (CN); Jinhan LI, Tianjin (CN); Haixia LI, Tianjin (CN); Huan WANG, Tianjin (CN); Zhenhua YAN, Tianjin (CN); Jun CHEN, Tianjin (CN)

(21) Appl. No.: 18/355,469

(22) Filed: Jul. 20, 2023

(30) Foreign Application Priority Data
Feb. 7, 2023 (CN) 202310069599.3

(51) Int. Cl. C30B 7/14; C30B 29/16; C30B 29/66

(52) U.S. Cl. CPC C30B 7/14; C30B 29/16; C30B 29/66

(57) ABSTRACT

Disclosed are a graded tip cuprous oxide single crystal material and a preparation method and application thereof. A first-level structure of the material is a regular octahedron, a second-level structure of the material is pyramid-shaped tips evenly distributed on the first-level structure, a size of the tip ranges from 40 nm to 180 nm, and a surface coverage degree ranges from 10% to 100%. The preparation method thereof comprises the following steps of: separating out a seed crystal from a mixed solution of copper soluble salt, concentrated brine, and strong alkali in advance to obtain a turbid liquid; and adding a reducing agent into the turbid liquid for seed-induced growth, adding excessive distilled water to dissolve the seed, and filtering, washing and drying to obtain the graded tip cuprous oxide single crystal material.

### CROSS REFERENCE TO RELATED APPLICATIONS

This application claims foreign priority of Chinese Patent Application No. 202310069599.3, filed on Feb. 7, 2023 in the China National Intellectual Property Administration, the disclosures of all of which are hereby incorporated by reference.

### TECHNICAL FIELD

The present invention belongs to the field of materials, and particularly relates to a graded tip cuprous oxide single crystal material and a preparation method and application thereof.

### BACKGROUND OF THE PRESENT INVENTION

In order to build a green and low-carbon circular economy in all aspects, China has put forward the development strategies of “peak carbon dioxide emissions in 2030” and “carbon neutrality in 2060”. Carbon dioxide reduction is an important carbon-negative emission technology in an electrochemical clean energy conversion strategy, which may convert intermittent energy unable to be used in time into chemical energy, and has the advantages of rich raw materials, mild reaction conditions, green and pollution-free properties, flexible electrolytic equipment, and the like. In various carbon dioxide reduction reaction products, multi-carbon compounds (ethylene, ethanol, propanol, and the like) are relatively stable and easy to store and transport, which hold a large combustion calorific value as chemical fuels and a large market share and as value-added chemical raw materials, so as to be widely concerned.

The key to electrochemically synthesize the multi-carbon compounds is to promote the coupling of low-carbon intermediates while inhibiting a hydrogen evolution reaction. A copper-based material has positive proton adsorption energy and moderate carbon monoxide adsorption energy, and is considered as one of the most potential materials for carbon dioxide reduction to produce multi-carbon compounds. In the prior art, electronic structures, valence states, crystal planes, defects, and other properties of the copper-based materials are adjusted mainly, which inhibit the hydrogen evolution reaction, and improves the intrinsic activity of a catalyst. However, because the coupling of the low-carbon intermediates has a high reaction energy barrier, there is still a challenge in the selective and low-energy-consumption electrochemical synthesis of the multi-carbon compounds, which hinders the large-scale application of carbon dioxide reduction.

Morphology engineering may change interfacial roughness, active area, infiltration degree, and even physical field intensity of an electrocatalyst, which is a powerful means to improve the activity and selectivity of an electrocatalytic reaction. In the prior art, a copper-based catalyst with a functional structure is developed mainly aiming at the problem of poor selectivity of the multi-carbon compounds. The non-patent document (J. Am. Chem. Soc. 2022, 144, 7, 3039-3049) and the “Chinese Journal of Catalysis” (Chin. J. Catal. 2022, 43, 519-525) reported that a tip with a special morphology and a high-curvature copper material had a positive effect on enhancing a local electric field, enriching cations and promoting C—C coupling, so as to improve the Faradaic efficiency of multi-carbon products. In the non-patent document (J. Am. Chem. Soc. 2020, 142, 13, 6400-6408), an oxide-derived copper catalyst with a nano-cavity morphology is constructed, which is capable of enriching reaction intermediates through a confinement effect by a porous cavity structure, so as to promote the production of the multi-carbon products. The Chinese patent (CN105883894A) discloses a layered flower-shaped cuprous oxide nano-material, which has a potential application value in carbon dioxide catalysis. Although the above strategies can effectively control the morphology of the copper-based material and achieve a positive effect in the application, a large number of templates or surfactants are used as sacrificial materials in the synthesis process in the strategies, which increases the synthesis cost and complexity. Therefore, it is of great significance to develop a synthesis technology of a special morphology catalyst with zero template, zero surfactant, economy and environmental protection, convenience, and high efficiency.

### SUMMARY OF PRESENT INVENTION

The present invention aims to solve the technical problems of a cuprous oxide material, such as a serious hydrogen evolution reaction, and strong selectivity of a single carbon product but poor selectivity of a high value-added multi-carbon product, and puts forward a strategy of constructing a graded tip catalyst structure by morphology engineering, and adopts a simple seed crystal-induced method to synthesize the catalyst by one step, thus realizing macro preparation without template and surfactant, and improving multi-carbon product selectivity of a material. The method of the present invention has an obvious modification effect, a low cost and a simple operation, and is suitable for large-scale production.

In order to achieve the above object, technical solutions of the present invention are as follows.

A graded tip cuprous oxide single crystal material is provided, wherein a first-level structure of the graded tip cuprous oxide single crystal material is a regular octahedron, a second-level structure of the graded tip cuprous oxide single crystal material is tips evenly distributed on the first-level structure, the tip has an oriented crystal plane and is pyramid-shaped, a size of the first-level structure ranges from 0.4 μm to 1.5 μm, a size of the tip ranges from 40 nm to 180 nm, and a surface coverage degree ranges from 10% to 100%.

A preparation method of the graded tip cuprous oxide single crystal material above is provided, which comprises the following steps of:
step 1: adding a copper soluble salt and a halogen salt into deionized water to prepare a salt solution A with a copper ion concentration of 0.001 mol/L to 0.1 mol/L and a halogen salt concentration of 3 mol/L of 4 mol/L, an alkali solution B with a hydroxyl concentration of 1 mol/L to 10 mol/L, and a reducing agent D with a concentration of 1 mol/L to 10 mol/L;
step 2: slowly dropwise adding the alkali solution B into the salt solution A, stirring the mixture for reaction at room temperature, adjusting a pH value of a turbid liquid through an addition amount of the alkali solution B, and immediately adding a solvent C when the pH value reaches a set value, so as to obtain a blue turbid liquid;
step 3: dropwise adding the reducing agent D into the blue turbid liquid, stirring the mixture for reaction, and adding excessive distilled water, so as to obtain a red turbid liquid; and
step 4: subjecting the red turbid liquid to suction filtering, and washing and drying in vacuum the obtained filter residue to obtain the graded tip cuprous oxide single crystal material.

Further, in the step 1, the copper soluble salt is one of sulfate, nitrate and chloride salt, and the copper ion concentration is preferably 0.003 mol/L to 0.007 mol/L, the halogen salt is one or more than two of LiCl, NaCl, and KCl, and is preferably NaCl and KCl, the alkali solution B is preferably sodium hydroxide of 3.5 mol/L to 5.5 mol/L, the solvent C is one of low polar molecules such as ethanol, isopropanol and ethylene glycol, and the reducing agent D is preferably an ascorbic acid of 3.5 mol/L to 5.5 mol/L.

Further, in the step 2, the pH value is controlled to be 8.3 to 14, and is preferably 10.5 to 13, the stirring speed is 300 rpm to 900 rpm, and is preferably 500 rpm to 700 rpm, and the volume fraction of the solvent C added is 15% to 50%, and preferably, 20% to 45% of ethanol is added.

Further, in the step 2, the reaction is carried out at a temperature of 20° C. to 70° C. and lasts for 10 minutes to 40 minutes, and preferably, the reaction is carried out at a temperature of 30° C. to 60° C. and lasts for 10 minutes to 15 minutes.

Further, in the step 3, a molar feeding ratio of the ascorbic acid to the copper salt is 1:1, and a mechanical stirring speed is 300 rpm to 900 rpm, and is preferably 500 rpm to 800 rpm.

Further, in the step 3, the reaction is carried out at a temperature of 20° C. to 70° C. and lasts for 0.5 hour to 2 hours, and preferably, the reaction is carried out at a temperature of 30° C. to 60° C. and lasts for 1 hour to 1.5 hours.

The present invention has the advantages and beneficial effects as follows.
1. Commonly used strategies of morphology engineering are a template method and a surfactant method. In these traditional strategies, the former requires a multi-step tedious process of template construction, product template growth, template removal, and the like; and the latter usually requires the addition of the surfactant hundreds of times higher than the target product, which is not conducive to large-scale production. According to the present invention, a seed crystal induced synthesis method is used as a one-pot method without needing the template and the surfactant, thus greatly reducing synthesis complexity and cost, and being easy to expand production.
2. According to the present invention, the row material has a low cost, the seed crystal is cheap, high-yield, and recyclable, the synthesis process is highly controllable, and by adjusting the halogen salt and the formula of the low polar solvent, second-level tip structures with different sizes and coverage degrees may be synthesized in an oriented way on a single crystal octahedral cuprous oxide main structure.
3. The present invention provides the graded tip cuprous oxide single crystal material, which not only has the advantages of high single crystal conductivity, strong stability, and the like, but also may form a high electric field at the tip to activate inert carbon dioxide molecules, thus improving the selectivity of reducing carbon dioxide into the multi-carbon product. By adjusting the second-level structure in an oriented way, Embodiment 3 may provide Faradaic efficiency of the multi-carbon product greater than 69% at −0.6 V (relative to a reversible hydrogen electrode RHE).

### DESCRIPTION OF THE DRAWINGS

FIG. 1 is a schematic diagram of a preparation process of a graded tip cuprous oxide single crystal material provided by the present invention, wherein MCI is a halogen salt and M is Li, Na, and K;

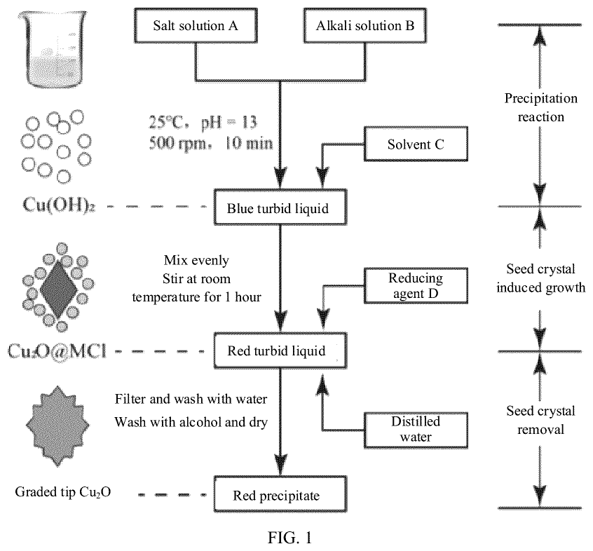

FIG. 2 is an SEM image of a graded tip cuprous oxide single crystal material in Embodiment 3 and a regularly octahedral cuprous oxide single crystal material in Comparative Example;

FIG. 3 is a TEM image of the graded tip cuprous oxide single crystal material in Embodiment 3 and the regularly octahedral cuprous oxide single crystal material in Comparative Example;

FIG. 4 is an XRD image of the graded tip cuprous oxide single crystal material in Embodiment 3 and the regularly octahedral cuprous oxide single crystal material in Comparative Example; and

FIG. 5 is a diagram of a performance of reducing carbon dioxide into a multi-carbon product of the material in Embodiment 3 and the material in Comparative Example.

### DETAILED DESCRIPTION OF PREFERRED EMBODIMENTS

The present invention is described in detail hereinafter with reference to the drawings and embodiments, but the implementation mode of the present invention is not limited to this.

### Embodiment 1

For a target-graded tip cuprous oxide single crystal material synthesized, a size of a second-level structure was 180 nm, and a surface coverage degree of the second-level structure was 50%. 2.930 g of copper sulfate and 222.5475 g of lithium chloride (a concentration of the lithium chloride was 3.5 mol/L) were respectively weighed to prepare 1.5 L of salt solution A. 1.920 g of sodium hydroxide was weighed to prepare 10 mL of alkali solution, and 2.113 g of ascorbic acid was weighed to prepare 10 mL of reducing agent solution.

The alkali solution was slowly dropwise added into the salt solution A, and stirred at a speed of 700 rpm for reaction at a temperature of 55° C. A pH value of a turbid liquid was adjusted to 11 through an addition amount of the alkali solution. 0.375 L of ethanol (equivalent to a volume fraction of 25%) was immediately added for reaction for 10 minutes, so as to obtain a blue turbid liquid.

The reducing agent solution was dropwise added into the blue turbid liquid, and stirred at a speed of 700 rpm for reaction at a temperature of 55° C., and the reaction lasted for 1 hour, so as to obtain a red turbid liquid. Excessive distilled water was added, a reaction solution was filtered, and a solid was washed with deionized water, and dried in vacuum to obtain the graded tip cuprous oxide single crystal material.

### Embodiment 2

This embodiment was different from Embodiment 1 in that, the lithium chloride was replaced by sodium chloride, and a concentration of the sodium chloride was controlled to be 4 mol/L. For a target-graded tip cuprous oxide single crystal material synthesized, a size of a second-level structure was 95 nm, and a surface coverage degree of the second-level structure was 100%.

### Embodiment 3

This embodiment was different from Embodiment 2 in that, the concentration of the sodium chloride was controlled to be 3.5 mol/L. For a target-graded tip cuprous oxide single crystal material synthesized, a size of a second-level structure was 95 nm, and a surface coverage degree of the second-level structure was 50%.

### Embodiment 4

This embodiment was different from Embodiment 2 in that, the concentration of the sodium chloride was controlled to be 3 mol/L. For a target-graded tip cuprous oxide single crystal material synthesized, a size of a second-level structure was 95 nm, and a surface coverage degree of the second-level structure was 20%.

### Embodiment 5

This embodiment was different from Embodiment 1 in that, the lithium chloride was replaced by potassium chloride, and a concentration of the potassium chloride was controlled to be 3.5 mol/L. For a target-graded tip cuprous oxide single crystal material synthesized, a size of a second-level structure was 40 nm, and a surface coverage degree of the second-level structure was 50%.

### Embodiment 6

This embodiment was different from Embodiment 3 in that, a volume fraction of ethanol was controlled to be 40%. For a target-graded tip cuprous oxide single crystal material synthesized, a size of a second-level structure was 95 nm, and a surface coverage degree of the second-level structure was 100%.

Morphologies and synthesis conditions of Embodiments 1 to 6 were as follows, and the other conditions were the same as those of Embodiment 1:

| | | Surface | | Concen- | |
|---|---|---|---|---|---|
| | Size of | coverage | | tration of | Addition |
| | second- | degree of | | halogen | amount |
| | level | second- | Type of | salt | of ethanol |
| | structure | level | halogen | solution | (volume |
| | (nm) | structure | salt | (mol/L) | fraction) |
| Embodi- | 180 | 50% | Lithium | 3.5 | 25% |
| ment 1 | | | chloride | | |
| Embodi- | 95 | 100% | Sodium | 4 | 25% |
| ment 2 | | | chloride | | |
| Embodi- | 95 | 50% | Sodium | 3.5 | 25% |
| ment 3 | | | chloride | | |
| Embodi- | 95 | 20% | Sodium | 3 | 25% |
| ment 4 | | | chloride | | |
| Embodi- | 40 | 50% | Potassium | 3.5 | 25% |
| ment 5 | | | chloride | | |
| Embodi- | 95 | 100% | Sodium | 3.5 | 40% |
| ment 6 | | | chloride | | |

### Comparative Example

In order to prove beneficial effects of a graded-tip cuprous oxide single crystal material, a graded-tip-free single crystal octahedral cuprous oxide contrast material was constructed.

2.930 g of copper sulfate and 36 g of polyvinylpyrrolidone homopolymer were respectively weighed to prepare 1.5 L of solution A. 1.920 g of sodium hydroxide was weighed to prepare 10 ml of alkali solution, and 2.113 g of ascorbic acid was weighed to prepare 10 ml of reducing agent solution.

The alkali solution was slowly added into the solution A for reaction at a temperature of 55° C., and stirred at a speed of 600 rpm, and the reaction lasted for 30 minutes to form a black turbid liquid.

The reducing agent solution was slowly added into the black turbid liquid for reaction at a temperature of 55° C., and stirred at a speed of 600 rpm, and the reaction lasted for 2 hours to obtain a red turbid liquid.

The red turbid liquid was filtered, and a solid was washed with deionized water, and dried in vacuum at 80° C. to obtain the tip-free single crystal octahedral cuprous oxide contrast material.

### Test Example

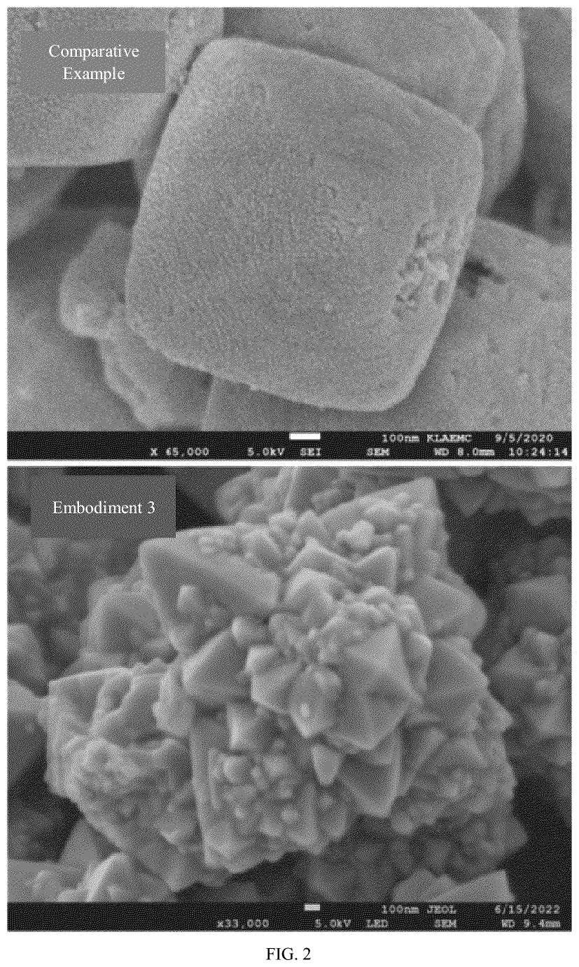

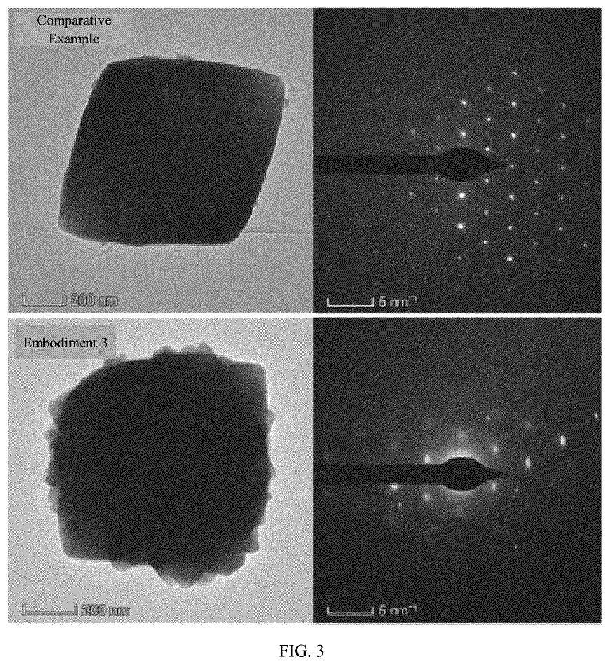

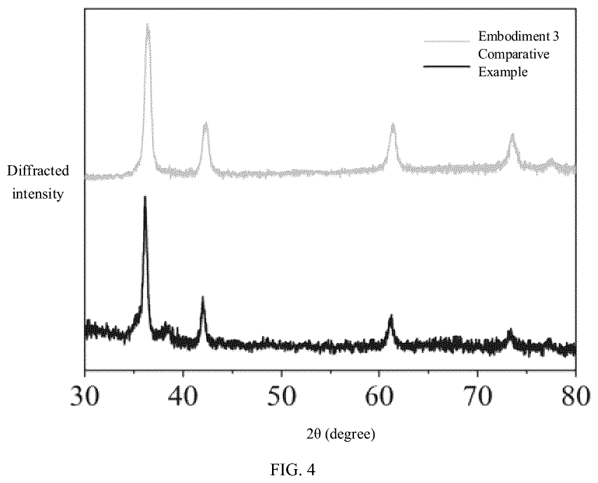

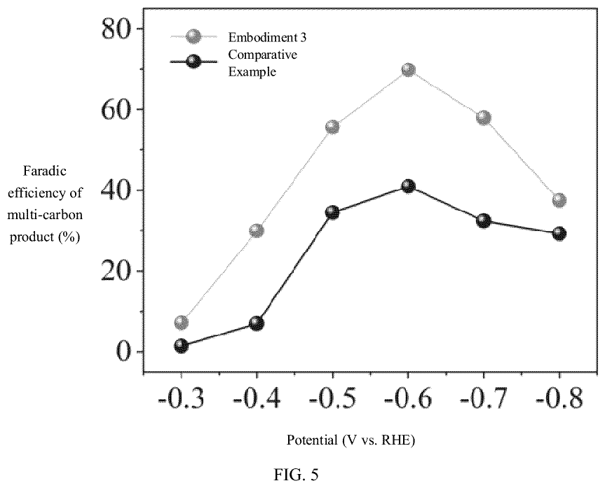

(1) Material characterization: the graded tip cuprous oxide single crystal material prepared in Embodiment 3 and the material in Comparative Example were characterized by SEM, results were shown in FIG. 2, and the two materials both had a good octahedral first-level structure. Embodiment 3 had a second-level pyramid-shaped tip structure with a size of 95 nm and a surface coverage degree of about 50%, and Comparative Example had no second-level structure. The graded tip cuprous oxide single crystal material prepared in Embodiment 3 and the material in Comparative Example were characterized by TEM, as shown in FIG. 3, there was a second-level structure on a surface of the material in the embodiment, while a surface of the material in Comparative Example was smooth, and diffraction patterns of the two materials both showed single crystal characteristics. The graded tip cuprous oxide single crystal material prepared in Embodiment 3 and the material in Comparative Example were characterized by XRD, and as shown in FIG. 4, the two materials both conformed to a Pn-3m space group structure, and had no obvious impurity peaks, indicating that the graded tip cuprous oxide single crystal material synthesized by the present invention had a high purity.
(2) Test environment: 100 mg of the graded tip cuprous oxide single crystal material prepared in Embodiment 3 and 100 mg of the material in Comparative were respectively weighed to mix with 50 μL of binder Nafion and 950 μL of isopropyl alcohol for pulping, dropwise coated on a carbon paper current collector of 1 cm², dried in the air, and then used as a working electrode. An auxiliary electrode was a platinum wire, a reference electrode was a Ag/AgCl electrode, and an electrolytic tank was H-shaped and separated by an anion exchange diaphragm, in which a volume of a cathode solution was 30 mL.
(3) Performance test: a Princeton P4000 electrochemical workstation was used, the test was carried out by chronoamperometry in a potential range of −0.3 V to −0.8 V (relative to a reversible hydrogen electrode RHE) for 1 hour, and a current was normalized by a geometric area of the electrode. Before the test, carbon dioxide was bubbled for 30 minutes in advance to reach saturation. During the test, a flow rate of the carbon dioxide was 10 sccm. In carbon dioxide reduction products, a gas phase product was quantitatively detected by an online gas chromatography hyphenated technology. 0.001 M dimethyl sulfoxide heavy water solution was prepared, wherein heavy water was a deuterated reagent, and dimethyl sulfoxide was an internal standard reagent. 100 μL of the internal standard solution above was added to 600 μL of the cathode solution after the reaction, and a liquid phase product dissolved in an electrolyte was quantitatively detected by hydrogen nuclear magnetic resonance spectrum quantification. As shown in FIG. 5, Embodiment 3 had the best performance at a potential of −0.6 V (relative to the reversible hydrogen electrode), and could provide Faradaic efficiency of multi-carbon product of 69%, while Comparative Example only provided Faradaic efficiency of multi-carbon product of 40% at an optimal potential.

To sum up, the above embodiments are only intended to illustrate relevant principles and implementation modes, and are not used to limit the present invention. Any modification, equivalent substitution, improvement, and the like made to the present invention without departing from the principles of the present invention should be included in the scope of protection of the present invention.

We claim:

1. A preparation method of a graded tip cuprous oxide single crystal material, comprising the following steps of:
step 1: adding a copper soluble salt and a halogen salt into deionized water to prepare a salt solution A with a copper ion concentration of 0.001 mol/L to 0.1 mol/L and a halogen salt concentration of 3 mol/L of 4 mol/L, an alkali solution B with a hydroxyl concentration of 1 mol/L to 10 mol/L, and a reducing agent D with a concentration of 1 mol/L to 10 mol/L, wherein the copper soluble salt is one or more than two of sulfate, nitrate and chloride salt of copper, the halogen salt is one or more than two of LiCl, NaCl, and KCl, the alkali solution B is a sodium hydroxide solution, and the reducing agent D is ascorbic acid;
step 2: slowly dropwise adding the alkali solution B into the salt solution A, stirring the mixture for reaction at 20° C. to 70° C. for 10 minutes to 40 minutes at a stirring speed of 300 rpm to 900 rpm, adjusting a pH value of a turbid liquid to be 8.3 to 14 through an addition amount of the alkali solution B, and immediately adding a solvent C when the pH value reaches a set value, wherein the solvent C is one or more than two of ethanol, isopropanol, and ethylene glycol, and a volume fraction of the solvent C added is 25% to 40%, so as to obtain a blue turbid liquid;
step 3: dropwise adding the reducing agent D into the blue turbid liquid at a molar feeding ratio of the reducing agent D to the copper soluble salt of 1:1, stirring the mixture for reaction at a reaction temperature of 20° C. to 70° C. for 0.5 hour to 2 hours at a stirring speed of 300 rpm to 900 rpm, and adding excessive distilled water, so as to obtain a red turbid liquid; and
step 4: subjecting the red turbid liquid to suction filtering, and washing and drying in vacuum the obtained filter residue to obtain the graded tip cuprous oxide single crystal material, wherein a first-level structure of the graded tip cuprous oxide single crystal material is a single crystal octahedron, a second-level structure of the graded tip cuprous oxide single crystal material is tips evenly distributed on the first-level structure, the tip has an oriented crystal plane, a size of the first-level structure ranges from 0.4 μm to 1.5 μm, a size of the second-level structure ranges from 40 μm to 180 μm, and a surface coverage degree ranges from 10% to 100%.

2. The preparation method of the graded tip cuprous oxide single crystal material according to claim 1, wherein the tip is pyramid-shaped.
